(19) United States
(12) Patent Application Publication
(10) Pub. No.: US 2009/0242061 A1
(43) Pub. Date: Oct. 1, 2009

(54) Dual-cavity fluid conveying apparatus

(75) Inventors: Shih Chang Chen, Hsin-Chu (TW); Ying Lun Chang, Hsin-Chu (TW); Rong Ho Yu, Hsin-Chu (TW); Shih Che Chiu, Hsin-Chu (TW); Tsung Pat Chou, Hsin-Chu (TW)

Correspondence Address: BACON & THOMAS, PLLC, 625 SLATERS LANE, FOURTH FLOOR, ALEXANDRIA, VA, 22314-1176, US

(73) Assignee: Microjet Technology Co., Ltd., Hsin-Chu (TW)

(21) Appl. No.: 12/385,026

(22) Filed: Mar. 30, 2009

(30) Foreign Application Priority Data
Mar. 31, 2008 (CN) 200810090957.4

(51) Int. Cl. B81B 7/00; F15C 3/00

(52) U.S. Cl. 137/831; 137/833

(57) ABSTRACT

A dual-cavity fluid conveying apparatus includes a flow-converging device, a first cavity body, and a second cavity body. The flow-converging device includes two sides corresponding to each other; a first channel and a second channel both passing through the two sides; and an inlet passage and an outlet passage both arranged between the two sides and communicated with the first channel and the second channel, respectively. The first cavity body and the second cavity body are symmetrically disposed at the two sides of the flow-converging device, wherein the first cavity body and the second cavity body each includes a valve cover disposed on one side of the flow-converging device, a valve membrane interposed between the one side of the flow-converging device and the valve cover, and an actuating device disposed circumferentially on the valve cover so as to define, together with the valve cover, a pressure chamber.

### BACKGROUND OF THE INVENTION

1. Field of the Invention

The present invention relates to a fluid conveying device, and more particularly, to a dual-cavity fluid conveying apparatus.

2. Description of Related Art

In following advancement of technologies, various fields, such as medicine, energy, computer technology, and printing are developed toward compact-size and mirco-size. As far as micropumps, sprayers, ink-jet printheads, or industrial printing devices are concerned, a fluid conveying apparatus involved therein is considered a key technique. Therefore, how to breakthrough technological bottlenecks by a creative technology turns out to be a significant issue of developments presently.

Referring to FIG. 1, an exploded view illustrating a conventional micropump structure, the micropump structure 1 comprises a valve seat 11, a valve cover 12, a valve membrane 13, an actuating device 14, and a pump cover 15. The valve membrane 13 includes an inlet valve structure 131 and an outlet valve structure 132. The valve seat 11 includes an inlet channel 111 and an outlet channel 112. A pressure chamber 123 is defined by and between the valve cover 12 and the actuating device 14. The valve membrane 13 is interposed between the valve seat 11 and the valve cover 12.

Upon a voltage acting on two poles located at top and bottom of the actuating device 14, an electric field will be effected to bend the actuating device 14. When the actuating device 14 deforms and bends upwardly to a direction X, an increased volume will occur in the pressure chamber 123, so that a suction force is produced and the inlet valve structure 131 of the valve membrane 13 is thus opened. This will make a fluid be sucked from the inlet channel 111 of the valve seat 11, and flow through the inlet valve structure 131 of the valve membrane 13 and an inlet valve channel 121 of the valve cover 12, and into the valve membrane 13. However, to the contrary, when the actuating 14 bends toward a direction opposite to the direction X due to a change of the electric field, the volume in the pressure chamber 123 will be compressed, such that a thrust will occur against the fluid inside the pressure chamber 123. This will make the inlet valve structure 131 and the outlet valve structure 132 of the valve membrane 13 subject to downward thrust, such that the outlet valve structure 132 is opened. The fluid will flow from the pressure chamber 123, through an outlet valve channel 122 of the valve cover 12, the outlet valve structure 132 of the valve membrane 13, and the outlet channel 112 of the valve seat 11, to the outside of the micropump structure 1. This will complete a fluid conveying process.

In spite of the fact that the conventional micropump structure 1 can still achieve the purpose of fluid conveyance, it adopts such a design that the mono-actuating device is incorporated with the mono-pressure chamber, the mono-flow conduit, the mono-inlet and outlet, and the mono-paired valve structure. In case the conventional micropump structure 1 is employed to increase amount of flow, it is necessary to stack up multiple micropump structures 1 and connect them with each other by a connection structure. However, such as manner of connection of multiple micropump structures 1 requires extra cost. Moreover, this kind of connection of multiple micropump structures 1 becomes bulky in size, and therefore, an increasing volume for the final products fail to meet such a trend of microlization.

It is understood, therefore, that to develop a dual-cavity fluid conveying apparatus so as to improve the defects inherent in the conventional art becomes an urge.

### SUMMARY OF THE INVENTION

The object of the present invention is to provide a dual-cavity fluid conveying apparatus characterized in employing a flow-converging device to integrate two sets of fluid conveying cavities into one set thereof. In other words, the first cavity body and the second cavity body are mirror symmetrically disposed at a first side and a second side, which are corresponding to each other, of the flow-converging device. Therefore, these two cavity bodies can act simultaneously so as to increase fluid flow, and to avoid the defects such as bulky volume and cost increase caused by stacking up two mono-cavity fluid conveying apparatuses, as the conventional art does.

To achieve the above-mentioned object, the present invention, in a broader sense, is to provide a dual-cavity fluid conveying apparatus for delivering fluids including liquids, gases, and so forth. The dual-cavity fluid conveying apparatus comprises a flow-converging device including two sides corresponding to each other, a first channel and a second channel both passing through the two sides, and an inlet passage and an outlet passage both being arranged between the two sides and being communicated with the first channel and the second channel, respectively; a first cavity body and a second cavity body symmetrically disposed at the two sides of the flow-converging device, wherein the first cavity body and the second cavity body each includes a valve cover disposed on one of the two sides of the flow-converging device, a valve membrane interposed between the one of the two sides of the flow-converging device and the valve cover, and an actuating device disposed circumferentially on the valve cover so as to define, together with the valve cover, a pressure chamber.

According to one of the aspects of the present invention, the valve membrane is provided with a valve structure and a second valve structure, both of the first valve structure and the second valve structure are hollow valve switches. The valve membrane is made of a material selected from polymer or metallic materials, wherein the valve membrane has a uniform thickness.

According to one of the aspects of the present invention, the valve membrane and the valve cover define together a first temporary-deposit area, and that the valve membrane and the one of the two sides of the flow-converging device define together a second temporary-deposit area.

According to one of the aspects of the present invention, the valve cover further includes a first valve passage and a second valve passage, both of the first valve passage and a second valve passage are communicated with the pressure chamber.

According to one of the aspects of the present invention, in each of the first cavity body and the second cavity body, the first valve structure, the first temporary-deposit area and the first valve passage correspond to the first channel of the flow-converging device; and the second valve structure, the second temporary-deposit area and the second valve passage correspond to the second channel of the flow-converging device.

According to one of the aspects of the present invention, the actuating device of the first cavity body has a vibration frequency the same as that of the actuating device of the second cavity body.

According to one of the aspects of the present invention, both of the first cavity body and the second cavity body further comprise a plurality of seal rings disposed on the two sides of the flow-converging device and in a plurality of recesses located on the valve cover of both of the first cavity body and the second cavity body. Part of each of the seal rings protrudes from each of the plurality of recesses, for applying a preforce to the valve membrane.

According to one of the aspects of the present invention, the first channel relates to a sub-channel, and the second channel relates to a flow-converging channel.

Other objects, advantages, and novel features of the present invention will become more apparent from the following detailed description when taken in conjunction with the accompanying drawings.

### BRIEF DESCRIPTION OF THE DRAWINGS

FIG. 1 is an exploded view illustrating a conventional micropump structure.

FIG. 2A is a perspective view illustrating a dual-cavity fluid conveying apparatus according to the present invention.

FIG. 2B is an exploded view of the dual-cavity fluid conveying apparatus shown in FIG. 2A.

FIG. 3 is a cross-sectional view, taken along cutting line a-a′ of FIG. 2A, illustrating a flow-converging device shown in FIG. 2A.

FIG. 4 is a cross-sectional view, taken along cutting line a-a′ of FIG. 2A, illustrating a valve cover shown in FIG. 2A.

FIG. 5A is a schematic view illustrating a valve membrane shown in FIG. 2B.

FIG. 5B is a schematic view illustrating an inlet valve structure in an opening status shown in FIG. 5A.

FIG. 5C is a schematic view illustrating an outlet valve structure in an opening status a shown in FIG. 5A.

FIG. 6A is a cross-sectional view, taken along cutting line a-a′ of FIG. 2A, illustrating the dual-cavity fluid conveying apparatus not yet operated, shown in FIG. 2A.

FIG. 6B is a cross-sectional view of the dual-cavity fluid conveying apparatus shown in FIG. 6A, while sucking a fluid.

FIG. 6C is a cross-sectional view of the dual-cavity fluid conveying apparatus shown in FIG. 6A, while discharging the fluid.

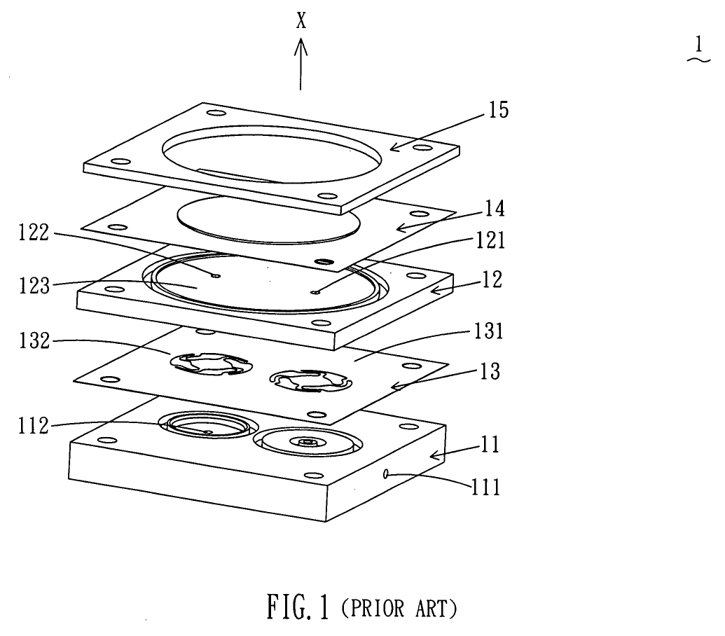

### DETAILED DESCRIPTION OF THE PREFERRED EMBODIMENTS

Exemplified embodiments realizing the features of the present invention will be described in detail hereafter. It should be understood that a variety of modifications, made in various modes and not away from the scope of the present invention, is possible. The following description and drawings are essentially for the purpose of explaining, but not for limiting the present invention.

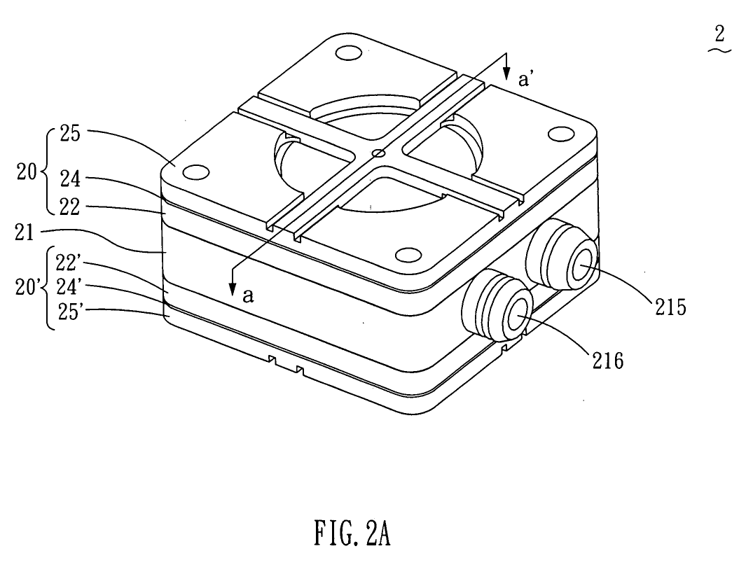

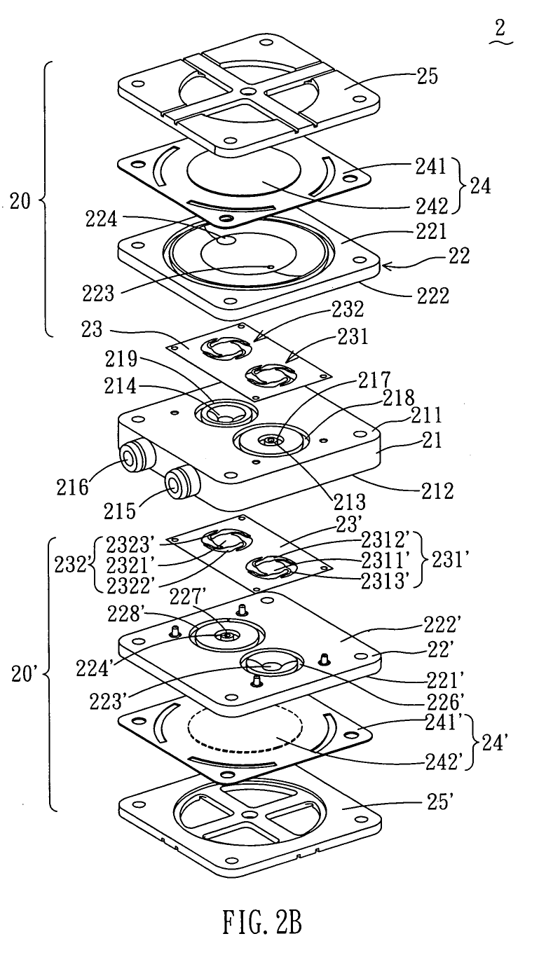

According to the present invention, the dual-cavity fluid conveying apparatus 2 can be employed in the industrial fields including, among others, medicine, biotechnology, energy, computer technology, and printing for the purpose of gas or fluid conveyance, but not limited to the fields listed above. Referring to FIGS. 2A and 2B, a perspective view and an exploded view illustrating a dual-cavity fluid conveying apparatus according to the present invention, the dual-cavity fluid conveying apparatus 2 comprises a first cavity body 20, a second cavity body 20′, and a flow-converging device 21. The first cavity body 20 includes a valve cover 22, a valve membrane 23, a actuating device 24, and a pump cover 25. The second cavity body 20′ includes a valve cover 22′, a valve membrane 23′, an actuating device 24′, and a pump cover 25′. The first cavity body 20 and the second cavity body 20′ are arranged opposite to, and mirror symmetrically with each other relative to the flow-converging device 21.

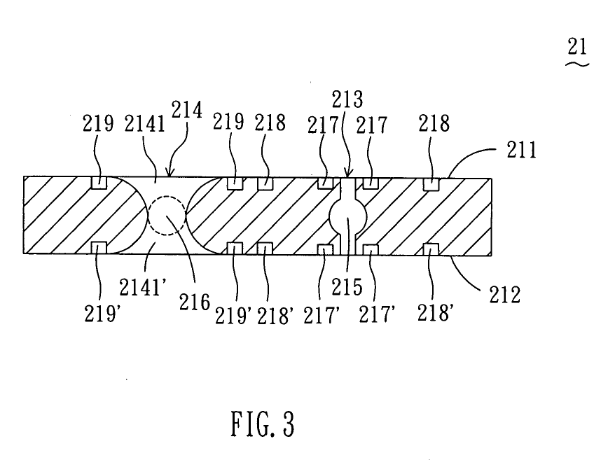

Further, referring to FIGS. 2A, 2B, and 3, wherein FIG. 3 is a cross-sectional view, taken along cutting line a-a′ of FIG. 2A, of the flow-converging device shown in FIG. 2A. The flow-converging device 21 is substantially formed as a rectangular structure, and includes a first side 211 and a second side 212 opposite to each other. Further, the flow-converging device 21 is provided with a first channel, a second channel, an inlet passage 215, and an outlet passage 216. In the present invention, the first channel can be a sub-channel 213 substantially perpendicularly passing through the first side 211 and the second side 212; whereas the second channel can be a flow-converging channel 214 substantially perpendicularly passing through the first side 211 and the second side 212. In other words, the sub-channel 213 opens co-axially both on the first side 211 and on the second side 212, and likewise for the flow-converging channel 214. In addition, the sub-channel 213 and the flow-converging channel 214 are independent from each other (as shown in FIG. 3). As a result, the first side 211 and the second side 212 of the flow-converging device 21 can be communicated with each other through the sub-channel 213 and the flow-converging channel 214. The inlet passage 215 and the outlet passage 216 relate to piping paths arranged between the first side 211 and the second side 212 of the flow-converging device 21. The inlet passage 215 is communicated with the first channel (i.e. the sub-channel 213), while the outlet passage 216 is communicated with the second channel (i.e. the flow-converging channel 214). To the effect, after assembly of the dual-cavity fluid conveying apparatus 2 is completed, the sub-channel 213, which is sealingly interposed between the first cavity body 20 an the second cavity body 20′, can be communicated with outside through the inlet passage 215; whereas the flow-converging channel 214 can be communicated with outside through the outlet passage 216.

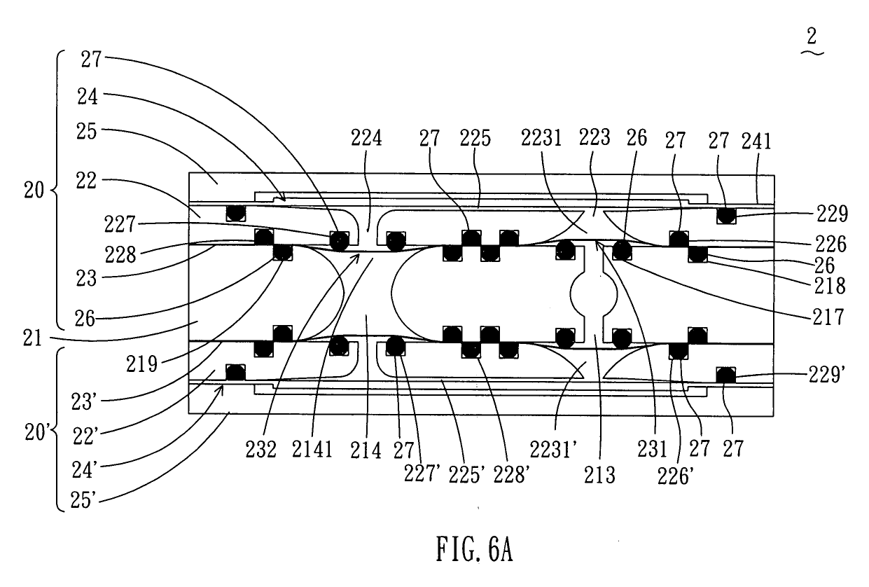

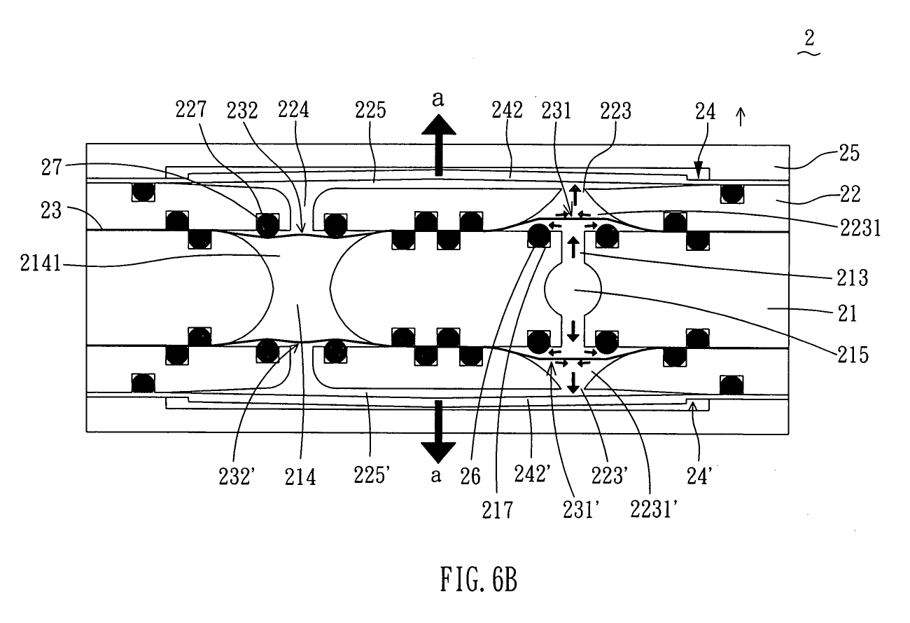

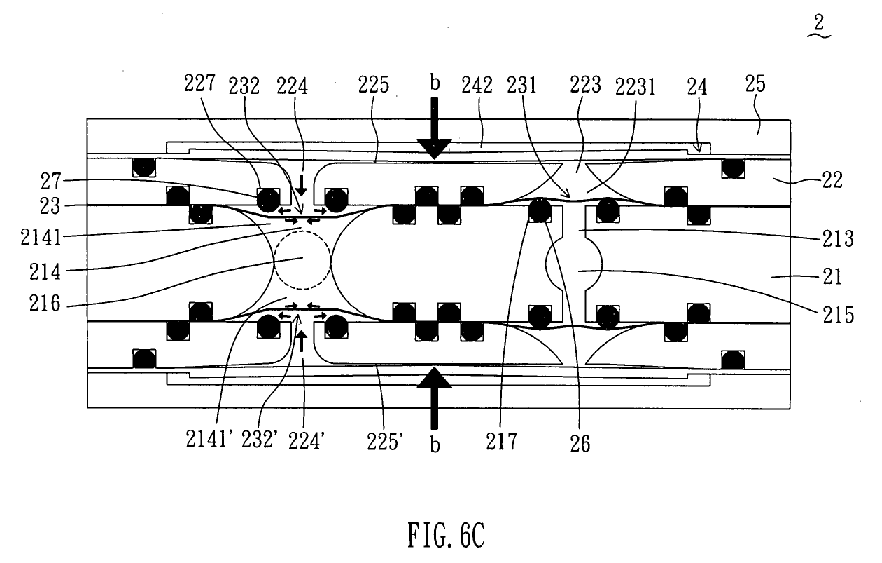

The flow-converging channel 214 of the flow-converging device 21 has one end flared to the first side 211 so as to define, together with the valve membrane 23 disposed on the first side 211, a second temporary-deposit area, for example, an outlet temporary-deposit area 2141 (as shown in FIG. 3 and in FIG. 6A). Of course, another temporary-deposit area 2141′ can also be provided in the flow-converging channel 214 adjacent to the second side 212 of the flow-converging device 21. As such, fluid fed in from the first cavity body 20 and the second cavity body 20′ can be baffled in the outlet temporary-deposit areas 2141, 2141 ′ and then flows smoothly in the flow-converging channel 214, and conveys out of the dual-cavity fluid conveying apparatus 2, along the outlet passage 216.

There are recess structures provided on the first side 211 and the second side 212 of the flow-converging device 21, wherein these recesses 217, 218, 217′, 218′ are centered with, and surround the sub-channel 213; while recesses 219, 219′ are centered with, and surround the flow-converging channel 214. A plurality of seal rings 26 are disposed in the recesses 217 to 219 and 217′ to 219′, as shown in FIG. 6.

According to the present invention, the flow-converging device 21 may be made of thermoplastic materials, such as polycarbonate (PC), polysulfone (PSF), Acrylonitrile Butadiene Styren (ABS), Linear low-density polyethylene (LLDEP), low-density polyethylene (LDPE), high-density polyethylene (HDPE), polypropylene (PP), [poly (phenylene sulfide) (PPS)], syndiotactic polystyrene (sPS), [polyphenylene oxide; polyphenyl ether (PPO)], polyoxymethylene (POM), [Poly (butylene terephthalate) (PBT)], Polyvinylidene Fluoride (PVDF), ethylene-tetra fluoroethylene (ETFE), Cyclo-olefin copolymer (COC), and so forth. The seal rings 26 may be made of chemistry-resistant soft material and be constituted as ring structures, such as methanol-resistant or acetic acid-resistant rubber rings, but not limited to the materials listed above.

Refer to FIGS. 2A and 2B, in the dual-cavity fluid conveying apparatus 2, according to the present invention, the valve membrane 23, the valve cover 22, the actuating device 24, and the pump cover 25 of the first cavity body 20 are stacked on the first side 211 of the flow-converging device 21, wherein the valve membrane 23 is interposed between the first side 211 of the flow-converging device 21 and the valve cover 22, and correspond to the flow-converging device 21 and the valve cover 22. The actuating device 24 is correspondingly arranged on the valve cover 22, and includes a diaphragm 241 and an actuator 242. The actuating device 24 can be driven and vibrated by voltage so as to actuate the dual-cavity fluid conveying apparatus 2. The pump cover 25 is disposed on the actuating device 24 and at one side opposite to the valve cover 22, for sealing the whole first cavity body 20. When the valve membrane 23, the valve cover 22, the actuating device 24, and the pump cover 25 are stacked up in sequence and secured by fastening means (not shown) on the first side 211 of the flow-converging device 21, the first cavity body 20 of the dual-cavity fluid conveying apparatus 2 can then be constituted. It is understood that the second cavity body 20′ of the dual-cavity fluid conveying apparatus 2 is disposed on the second side 212 of the flow-converging device 21, and is, relative to the flow-converging device 21, mirror symmetrically arranged opposite to the first cavity body 20 (see FIG. 2B and FIG. 6A). Therefore, the following description is exemplified with the first cavity body 20 for explaining, in detail, structure of the dual-cavity fluid conveying apparatus 2.

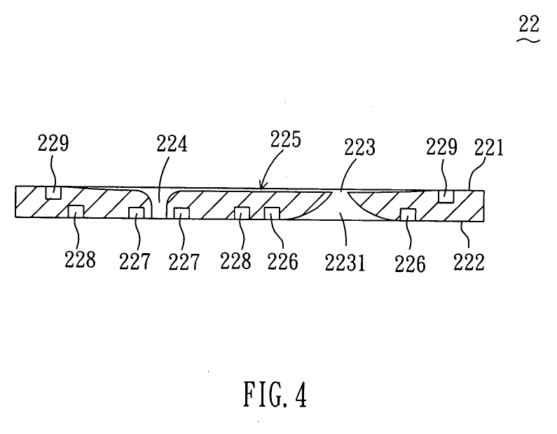

Now referring to FIGS. 2A, 2B, and 4, wherein FIG. 4 is a cross-sectional view taken along cutting line a-a′ of FIG. 2A illustrating a valve cover shown in FIG. 2A, the valve cover 22 is disposed on the first side 211 of the flow-converging device 21, and includes a first upper surface 221 and a first lower surface 222, wherein the first lower surface 222 faces the first side 211 of the flow-converging device 21.The valve membrane 23 is interposed between the first lower surface 222 and the first side 211. Further, the valve cover 22 is provided with a first valve passage and a second valve passage both passing through the first upper surface 221 and the first lower surface 222. In the present invention, the first valve passage refers to an inlet valve passage 223, and the second valve passage refers to an outlet valve passage 224, wherein the inlet valve passage 223 corresponds to the sub-channel 213 of the flow-converging device 21, and the outlet valve passage 224 corresponds to the outlet temporary-deposit area 2141 and the flow-converging channel 214 of the flow-converging device 21 (as shown in FIG. 6A). In addition, the inlet valve passage 223 of the valve cover 22 flares to the first lower surface 222 so as to define, together with the valve membrane 23, a first temporary-deposit area. According to the present invention, the first temporary-deposit area is partially concaved at the position corresponding to the inlet valve passage 223, so as to form an inlet temporary-deposit area 2231 on the first lower surface 222 of the valve cover 22 (as shown in FIG. 4 and FIG. 6A).

Further referring to FIG. 4, the first upper surface 221 of the valve cover 22 is partially concaved so as to define, together with the correspondingly arranged actuator 242 of the actuating device 24, a pressure chamber 225 (see FIG. 4 and FIG. 6A). The pressure chamber 225 is communicated with the inlet temporary-deposit area 2231 through the inlet valve passage 223, and as well, the pressure chamber 225 is communicated with the outlet valve passage 224. Further, there are recess structures provided on the valve cover 22, wherein a recess 226 is centered with, and surround the inlet valve passage 223, while recesses 227, 228 are centered with and surround the outlet valve passage 224 on the first lower surface 222 of the valve cover 22. Besides, on the first upper surface 221 of the valve cover 22, there is provided with a recess 229 surrounding the pressure chamber 225. There are seal rings 27 disposed in the recesses 226 to 229 (see FIG. 6A). The valve cover 22 may be made of thermoplastic material of the kind similar to that of the flow-converging device 21, whereas the seal rings 27 can be made of the same material as that of the seal rings 26, and no further description therefor is necessary.

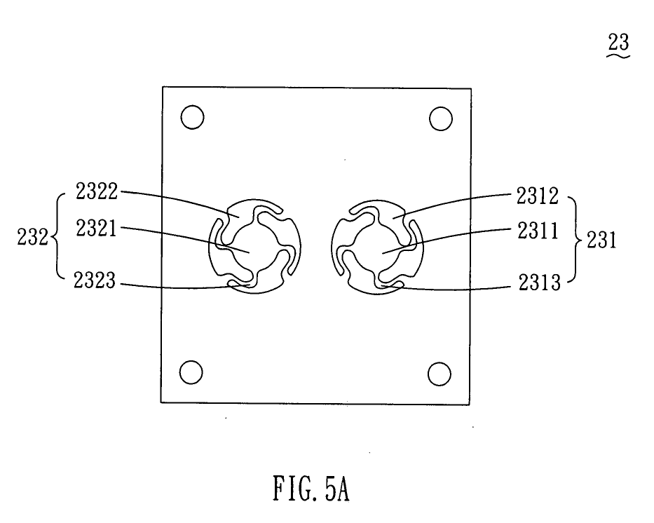

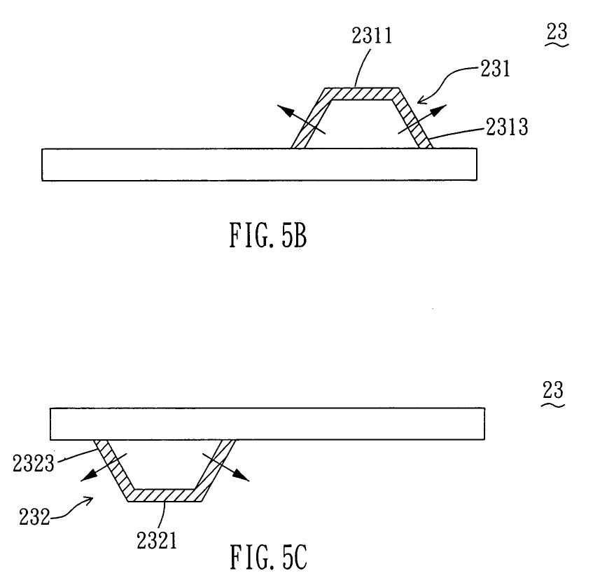

Referring to FIG. 2B, and 5A, wherein FIG. 5A is a schematic view illustrating the valve membrane shown in FIG. 2B, the valve membrane 23 is provided with a plurality of valve structures which are hollow valve switches. In the present invention, the valve membrane 23 includes a first hollow valve structure and a second hollow valve structure, namely an inlet valve structure 231 and an outlet valve structure 232. The inlet valve structure 231 corresponds to the sub-channel 213 of the flow-converging device 21, and to the inlet valve passage 223 and the inlet temporary-deposit area 2231 of the valve cover 22; whereas the outlet valve structure 232 corresponds to the flow-converging channel 214 and the outlet temporary-deposit area 2141 of the flow-converging device 21, and to the outlet valve passage 224 of the valve cover 22 (as shown in FIG. 6A).

Refer to FIG SA, the inlet valve structure 231 is provided with an inlet valve blade 2311, and a plurality of vents 2312 surrounding the inlet valve blades 2311. There are also provided with valve arms 2313 in connection with the inlet valve blade 2311 and located between the vents 2312. Similarly, the outlet valve structure 232 includes an outlet valve blade 2321, vents 2322, and valve arms 2323, acted in a manner same as those of the inlet valve structure 231. As such, no further description therefor is necessary. In the present invention, the valve membrane 23, substantially, relates to a flexible membrane having a uniform thickness. The valve membrane 23 may be made of materials selected, but not limited from, chemistry-resistant organic polymer such as Polyimide (PI), or metallic materials such as aluminum, nickel, stainless steel, copper or aluminum alloy.

In case the valve membrane 23 made of Polyimide, photosensitive photoresist is first coated thereon so as to proceed with exposure and development. Then, a reactive ion etching (RIE) is proceeded, so as to form the vents 2312, 2322 of the valve membrane 23. Further, in case the valve membrane 23 made of stainless steel, lithography and etching can be proceeded, so as to form photoresist patterns on the stainless steel plate. Subsequently, the valve membrane 23 is dipped in a solvent mixed with FeCl₃ and HCL, so as to proceed with a wet etching and then the vents 2312, 2322 are formed. Or in case the valve membrane 23 made of nickel, similarly a lithography and etching is applied, so as to form photoresist patterns on a stainless steel substrate. Then, a nickel electroforming is undertaken. The area covered with the photoresist cannot be electroformed, so that upon proceeding with the nickel electroforming for a certain thickness on the stainless steel plate, the nickel at the area covered with the photoresist will be removed, such that the valve membrane 23 can be obtained. Of course, the method for producing the valve membrane 23 is not limited to those mentioned above. Other methods such as precision punching, conventional mechanical machining, laser machining, and electric discharging can all be applied to make the valve membrane 23.

Since the valve membrane 23 can be a flexible thin sheet, as the valve membrane 23 is interposed between the first side 211 of the flow-converging device 21 and the valve cover 22, once the value membrane be subject to a suction force produced by the increase of volume of the pressure chamber 225, the inlet valve structure 231 and the outlet valve structure 232 should move together toward the pressure chamber 225. But in fact, due to the difference in the structure between the position 5 adjacent to the inlet valve passage 223 and to the outlet valve passage 224 of the first lower surface 222 of the valve cover 22 (as shown in FIG. 4), a negative pressure difference in the pressure chamber 225 only causes the inlet valve structure 231 moves upwardly toward the valve cover 22, while the outlet valve structure 232 sticks to the first lower surface 222 of the valve cover 22 and cannot be opened (as shown in FIG. 5B and FIG. 6B). Under the circumstances, the fluid can only flow, from one side of the valve membrane 23 adjacent to the flow-converging device 21, to the other side of the valve membrane 23 adjacent to the valve cover 22, through the vents 2312 of the inlet valve structure 231 (as indicated with the arrows in FIG. 5B), and then flow into the inlet temporary-deposit area 2231 of the valve cover 22 and into the inlet valve passage 223. Therefore, the fluid can be conveyed to the pressure chamber 225, and with the help of the closure of the outlet valve structure 232, a reverse flow of the fluid can be avoided.

Likewise, because the structure adjacent to the sub-channel 213 of the first side 211 of the flow-converging device 21 and the structure adjacent to the flow-converging channel 214 are different with each other (as shown in FIG. 3), when the valve membrane 23 is subject to a positive pressure of the pressure chamber 225 and to a downward force, only the outlet valve structure 232 can moves downwardly toward the flow-converging device 21, while the inlet valve structure 231 sticks downwardly on the first side 211 of the flow-converging device 21 and seals the sub-channel 213 of the flow-converging device 21. Namely, the inlet valve structure 231 cannot be opened (see FIG. 5C and FIG. 6C). As a result, the fluid can only flow, from the pressure chamber 225, to the outlet temporary-deposit area 2141 of the flow-converging device 21, through the vents 2322 of the outlet valve structure 232. Therefore, according to the present invention, the inlet valve structure 231 can open or close rapidly in response to a negative pressure or a positive pressure produced by the pressure chamber 225. The outlet valve structure 232 can then control the flowing direction of the fluid in response to the open or closure of the inlet valve structure 231, so as to avoid a reverse flow of the fluid. It should be noted that in order to clearly indicate the action of the valve membrane 23, the valve cover 22 and the flow-converging device 21 are not shown in FIGS. 5B and 5C.

Further referring to FIG. 2B, the actuating device 24 includes a diaphragm 241 and a actuator 242, wherein the diaphragm 241 is fixed circumferentially to the valve cover 22 so as to define, together with the valve cover 22, the pressure chamber 225 (as shown in FIG. 6A). For various embodiments of the present invention, the diaphragm 241 maybe made of mono-layer metallic structure formed with mono-layer metal, for instance, but not limited to, stainless steel or copper. On the other hand, the diaphragm 241 may be affixed, on the metallic layer, an additional sheet of biochemistry-resistant material so as to form a dual-layer structure. The actuator 242 can be affixed on the diaphragm 241, wherein the actuator 242 relates to a piezoelectric plate made of piezoelectric powder of lead zirconium titanate (PZT) series having a high piezoelectric coefficient. The pump cover 25 is correspondingly arranged on the actuating device 24, such that the first cavity body 20 can be formed by interposing the valve membrane 23, the valve cover 22 and the actuating device 24 in between the pump cover 25 and the flow-converging device 21, as shown in FIG. 6A.

Now referring to FIGS. 2A, 2B and 6, wherein FIG. 6A is a cross-sectional view, taken along cutting line a-a′ of FIG. 2A, illustrating the dual-cavity fluid conveying apparatus not yet operated, according to the present invention shown in FIG. 2A, after the first cavity body 20 has been assembled on the first side 211 of the flow-converging device 21, the sub-channel 213 of the flow-converging device 21 is arranged correspondingly to the inlet valve structure 231 of the valve membrane 23, the inlet temporary-deposit area 2231 of the valve cover 22, and the inlet valve passage 223; while the flow-converging channel 214 of the flow-converging device 21 corresponds to the outlet temporary-deposit area 2141, the outlet valve structure 231 of the vale membrane 23, and the outlet valve passage 224 of the valve cover 22.

Still further, the seal ring 26 received in the recess 217 surrounding the sub-channel 213 of the flow-converging device 21 has a thickness greater than the depth of the recess 217. Therefore, the seal ring 26, in part, protrudes from the recess 217, and constitutes a micro-protrusion structure. As a result, the inlet valve blade 2311 of the inlet valve structure 231 of the valve membrane 23, due to the micro-protrusion structure, protrudes upwardly. That is, the micro-protrusion structure presses on the valve membrane 23, thus inducing a preforce action against the inlet valve structure 231. This will help to produce a greater tightening effect at the release of the fluid, so as to prevent a reverse flow of the fluid, and to produce a clearance between the inlet valve blade 2311 and the first side 211 of the flow-converging device 21, making the inlet valve blade 2311 open easily while the flow-in of the fluid. Likewise, the seal ring 27, along with the recess 227 surrounding the outlet valve passage 224 at the first lower surface 222 of the valve cover 22, also constitutes a micro-protrusion structure. This makes the outlet valve structure 232 of the valve membrane 23 protrude downwardly, such that the valve cover 22 protrudes correspondingly downwardly, and that a clearance is also formed between the outlet valve blade 2321 and the first lower surface 222 of the valve cover 22. The micro-protrusion structures at the outlet valve structure 232, and at the inlet valve structure 231, are arranged opposite to each other and function similarly. As such, no further description thereto is necessary. The micro-protrusion structures, as mentioned above, not only can be formed by a combination of the recesses 217, 227 and the seal rings 26, 27; but also, for other embodiments of the present invention, but also can be formed by semi-conductor manufacturing processes, for instance, lithography and etching, coating, or electroforming, so as to form the micro-protrusion structures on the flow-converging device 21 and on the valve cover 22 directly, or to form the micro-protrusion structures integrally with basic materials constituting the flow-converging device 21 and the valve cover 22 by injection molding, wherein the basic materials may be, among others, thermoplastic. The rest part of the valve membrane 23, however, are laid between the valve cover 22 and the flow-converging device 21; and through the arrangement of the seal rings 26, 27 received in the recesses 218, 219 and 226, 228, 229, a tightening engagement can be obtained among structures. As a result, leakage of the fluid can be avoided.

Reference is made again to FIG. 6A. The second cavity body 20′ includes a valve cover 22′, a valve membrane 23′, an actuating device 24′, and a pump cover 25′, which are arranged on the second side 212 of the flow-converging device 21, and are mirror symmetrically with the first cavity body 20 relative to the flow-converging device 21. Since the second cavity body 20′ and the first cavity body 20 are similar to each other in terms of structure and function, the following description is made only for the first cavity body 20 as far as conveyance of the fluid is concerned. It is understood that when the dual-cavity fluid conveying apparatus 2, according to the present invention, is actually implemented, the first cavity body 20 and the second cavity body 20′ are operated with the same measure, and simultaneously, for fluid conveyance.

Referring to FIG. 6B, a cross-sectional view of the dual-cavity fluid conveying apparatus shown in FIG. 6A, while sucking the fluid, as voltage is applied to the actuator 242, the actuating device 24 will be bent upwardly, as indicated by an arrow a. This will increase volume of the pressure chamber 225 and produce a negative-pressure difference, and thus form a suction force. The inlet valve structure 231 and the outlet valve structure 232 of the valve membrane 23 will therefore be subject to an upward drawing force due to the negative pressure. Under the circumstances, the inlet valve blade 2311 of the inlet valve structure 231 will be opened rapidly with the help of the preforce provided by the micro-protrusion structures constituted by the recess 217 and the seal ring 26 (see FIG. 5B). As such, a great amount of the fluid will be sucked into the flow-converging device 21 through the inlet passage 215, and will be distributed at the sub-channel 213, so that part of the fluid will flow into the first cavity body 20, and through the vents 2312 of the inlet valve structure 231 of the valve membrane 23, so as into the inlet temporary-deposit area 2231 and the inlet valve passage 223 of the valve cover 22, and then into the pressure chamber 225. At this moment, the outlet valve structure 232 of the valve membrane 23 is subject to the upward drawing force. Besides, the structure at the first lower surface 222 of the valve cover 22 corresponding to the outlet valve structure 232 is different from that corresponding to the inlet valve structure 231. Further, the recess 227 and the seal ring 27 can provide a pre-tightening effect. As a result, the outlet valve blade 2321 of the outlet valve structure 232 of the valve chamber 23 will, with the help of the upward-drawing force, seal the outlet valve passage 224, such that a reverse flow of the fluid will not take place.

Further referring to FIG. 6C, a cross-sectional view of the dual-cavity fluid conveying apparatus shown in FIG. 6A, while discharging the fluid, as the direction of electric field applied to the actuator 242 has changed and made the actuator 242 bent downwardly, as indicated by an arrow b, the actuating device 24 will be bent downwardly as well. This will compress and reduce the volume of the pressure chamber 225, and will produce a positive-pressure difference relative to outside, and thus form a thrust against the fluid inside the pressure chamber 225, making the fluid flow, through the outlet valve passage 224, out of the pressure chamber 225 in a great amount transiently. The inlet valve structure 231 and the outlet valve structure 232 of the valve membrane 23 will then be subject to a downward pushing force due to the positive pressure. Under the circumstances, the outlet valve blade 2321 of the outlet valve structure 232 will be opened rapidly, with the help of a preforce (see FIG. 5C), such that the fluid will flow from the pressure chamber 225, through the outlet valve passage 224 of the valve cover 22, the vents 2322 of the outlet valve structure 232 of the valve membrane 23, and into the outlet temporary-deposit area 2141 and the flow-converging channel 214 of the flow-converging device 21 (see FIG. 6C). Eventually, the fluid flows out of the dual-cavity fluid conveying apparatus 2 through the outlet passage 216, and thus finishes the process of fluid conveyance.

On the other hand, when the inlet valve structure 231 is subject to the downward thrust, because the structure adjacent to the sub-channel 213 of the first side 211 of the flow-converging device 21 and the structure adjacent to the flow-converging channel 214 are different from each other, and because the recess 217 and the seal ring 26 can provide a pre-tightening effect, the inlet valve blade 2311 will seal the sub-channel 213, so that the inlet valve structure 231 is pressed to be in a close status (as shown in FIG. 5C). As such, the fluid cannot flow through the inlet valve structure 231, and that a reverse flow of the fluid will not take place. When the actuator 242 is actuated again by the voltage and the actuating device 24 is protruded upwardly so as to increase the volume of the pressure chamber 225, the fluid temporarily stored in the inlet temporary-deposit area 2231 of the valve cover 22 will flow through the inlet valve passage 223 and into the pressure chamber 225; and when the actuating device 24 is protruded downwardly, the fluid is discharged from the pressure chamber 225. Therefore, by changing the direction of the electric field, the actuating device 24 is driven reciprocally so as to draw in or release out the fluid from the dual-cavity fluid conveying apparatus 2 and to achieve the purpose of fluid conveyance.

It is understood, therefore, that through incorporation of the actuator 242, the diaphragm 241, the pressure chamber 225, and the valve membrane 23, the inlet valve structure 231 and the outlet valve structure 232 of the valve membrane 23 can be closed and opened, making the fluid flow in a mono-direction. In addition, this will make the fluid flow through the pressure chamber 225 of the first cavity body 20 in a great amount.

As mentioned above, when the dual-cavity fluid conveying apparatus 2, according to the present invention, is implemented with, the first cavity body 20 and the second cavity body 20′ are operated simultaneously. In other words, the vibration frequency of an actuator 242′ of the actuating device 24′ of the second cavity body 20′ is the same as that of the actuator 242 of the actuating device 24 of the first cavity body 20. Therefore, when the actuators 242/242′ act mirror symmetrically with each other, and move toward the direction as indicated by arrow a shown in FIG. 6B, the volumes of the pressure chambers 225/225′ will be increased, fluid from outside is sucked through the inlet passage 215 and into the flow-converging device 21, and then distributed at the sub-channel 213 and flows toward the first cavity body 20 and the second cavity body 20′, and through the inlet valve structures 231/231′, the inlet temporary-deposit areas 2231/2231′, the inlet valve passages 223/223′, and into the pressure chambers 225/225′. Whereas in case the volumes of the pressure chambers 225/225′ are compressed by the actuators 242/242 (as indicated by arrow b shown in FIG. 6C), the fluid will be discharged from the pressure chambers 225/225′, and will flow through the outlet valve passages 224/224′, the outlet valve structures 232/232′ and the outlet temporary-deposit areas 2141/2141′, and to the flow-converging channel 214 of the flow-converging device 21, and then flow out of the dual-cavity fluid conveying apparatus 2 through the outlet passage 216. It is understood, therefore, that the dual-cavity fluid conveying apparatus 2, according to the present invention, has a merit in providing an amount of fluid flow double than that of the conventional mono-cavity fluid conveying apparatus, without, however, increasing a double volume. To the effect, the dual-cavity fluid conveying apparatus 2, according to the present invention, raises the fluid flow to a double amount, while the volume thereof is not a summation of two mono-cavity fluid conveying apparatuses. As such, the present invention indeed meets the trend of microlization on products.

In view of the above, the dual-cavity fluid conveying apparatus 2, according to the present invention, can be applied to a micropump structure, and is characterized by incorporating two fluid conveying cavity bodies into an integral one, namely, by staking up two sets of valve membranes, valve covers and actuating devices on the first side and the second side of the flow-converging devices, respectively, so as to form two fluid conveying cavity bodies mirror symmetrically with each other. Because the flow-converging device is provided with the sub-channel and the flow-converging channel in communication with the first side and the second side, and because the first cavity body and the second cavity body are each proved with the an actuating device, a synchronic driving of the actuating devices will suck in the fluid to flow through the inlet channel and into the dual-cavity fluid conveying apparatus. The fluid is then distributed by the sub-channel to the first cavity body and the second cavity body, and then the fluid output from the first cavity body and the second cavity body is converged and input to the flow-converging channel and thereafter output to the outside through the outlet channel. As compared to the conventional mono-cavity fluid conveying apparatus, the present invention not only increases the fluid flow to a double volume, but also decreases its volume to one less than stacking up two mono-cavity fluid conveying apparatuses. In particular, through the present invention, engaging mechanism for stacking up plural micropumps can be eliminated. Therefore, the present invention not only saves cost and reduces dimension and improves the effect of a fluid conveying apparatus.

Further, when the actuating devices provided inside of the first cavity body and the second cavity body of the dual-cavity fluid conveying apparatus, according to the present invention, are actuated piezoelectrically and that the pressure chambers change their volumes, the inlet/outlet valve structures of the valve membranes can be closed or opened rapidly. Besides, by incorporating the valve membranes with the micro-protrusion structures constituted by the recesses and the seal rings on the flow-converging device and on the valve covers, a reverse flow of the fluid will not take place and that the fluid will be conveyed in a direction as designated.

Still further, the dual-cavity fluid conveying apparatus, according to the present invention, is provided for conveying either gas or fluid, which not only has a desirable fluid rate and output pressure, with possibility of initial self-suction of fluid, but also has a precision manipulation. On the other hand, since the dual-cavity fluid conveying apparatus, according to the present invention, can also be employed to convey gases, bubbles can be removed during the process of fluid conveyance so as to achieve a high-efficient fluid conveyance. These advantages, indeed, cannot be possibly achieved by the conventional art.

Although the present invention has been explained in relation to its preferred embodiments, it is to be understood that many other possible modifications and variations can be made without departing from the scope of the invention as hereinafter claimed.

What is claimed is:

1. A dual-cavity fluid conveying apparatus, for delivering a fluid, comprising:
a flow-converging device, including:
two sides corresponding to each other;
a first channel and a second channel, both of the first channel and the second channel passing through the two sides; and
an inlet passage and an outlet passage, both of the inlet passage and the outlet passage being arranged between the two sides, and being communicated with the first channel and the second channel, respectively;
a first cavity body and a second cavity body, being symmetrically disposed at the two sides of the flow-converging device, wherein the first cavity body and the second cavity body each includes:
a valve cover, being disposed on one of the two sides of the flow-converging device;
a valve membrane, being interposed between the one of the two sides of the flow-converging device and the valve cover; and
an actuating device, being disposed circumferentially on the valve cover so as to define, together with the valve cover, a pressure chamber.

2. The dual-cavity fluid conveying apparatus as claimed in claim 1, wherein the valve membrane is provided with a first valve structure and a second valve structure, both of the first valve structure and the second valve structure are hollow valve switches.

3. The dual-cavity fluid conveying apparatus as claimed in claim 2, wherein the valve membrane and the valve cover define together a first temporary-deposit area, and the valve membrane and the one of the two sides of the flow-converging device define together a second temporary-deposit area.

4. The dual-cavity fluid conveying apparatus as claimed in claim 3, wherein the valve cover further includes a first valve passage and a second valve passage, both of the first valve passage and a second valve passage are communicated with the pressure chamber.

5. The dual-cavity fluid conveying apparatus as claimed in claim 4, wherein the first valve structure, the first temporary-deposit area and the first valve passage correspond to the first channel of the flow-converging device; and the second valve structure, the second temporary-deposit area and the second valve passage correspond to the second channel of the flow-converging device, in both of the first cavity body and the second cavity body.

6. The dual-cavity fluid conveying apparatus as claimed in claim 1, wherein the actuating device of the first cavity body has a vibration frequency the same as that of the actuating device of the second cavity body.

7. The dual-cavity fluid conveying apparatus as claimed in claim 1, wherein the actuating device includes an actuator and a diaphragm.

8. The dual-cavity fluid conveying apparatus as claimed in claim 1, wherein both of the first cavity body and the second cavity body further comprise a plurality of seal ring, the plurality of seal rings are disposed on the two sides of the flow-converging device and in a plurality of recesses located on the valve cover of both of the first cavity body and the second cavity body; and part of each of the seal rings protrudes from each of the plurality of recesses, for applying a preforce to the valve membrane.

9. The dual-cavity fluid conveying apparatus as claimed in claim 1, wherein the valve membrane is made of a material selected from polymer or metallic materials, and the valve membrane has a uniform thickness.

10. The dual-cavity fluid conveying apparatus as claimed in claim 1, wherein the first channel relates to a sub-channel, and the second channel relates to a flow-converging channel.
